(19) United States
(12) Patent Application Publication
(10) Pub. No.: US 2024/0224592 A1
(43) Pub. Date: Jul. 4, 2024

(54) THIN FILM TRANSISTOR, MANUFACTURING METHOD THEREOF AND DISPLAY APPARATUS COMPRISING THE SAME

(71) Applicant: LG Display Co., Ltd., Seoul (KR)

(72) Inventors: DaeHwan KIM, Paju-si (KR); Jaeman JANG, Paju-si (KR); Uyhyun CHOI, Paju-si (KR); Min-Gu KANG, Paju-si (KR); KyungChul OK, Paju-si (KR); SeungChan CHOI, Paju-si (KR)

(21) Appl. No.: 18/454,273

(22) Filed: Aug. 23, 2023

(30) Foreign Application Priority Data
Dec. 29, 2022 (KR) 10-2022-0188532

(51) Int. Cl. H10K 59/121; G09G 3/3233; H10K 59/12; H10K 59/126

(52) U.S. Cl. CPC H10K 59/1213; G09G 3/3233; H10K 59/1201; H10K 59/126; G09G 2300/0842

(57) ABSTRACT

A thin film transistor, a manufacturing method of the thin film transistor and display apparatus including the thin film transistor are provided. The thin film transistor comprises an active layer and a gate electrode that partially overlaps the active layer, wherein the active layer includes a channel portion, a first connection portion contacting one side, namely a first side, of the channel portion and a second connection portion spaced apart from the first connection portion and contacting the other side, namely a second side of the channel portion, wherein the channel portion includes a first channel part overlapping the gate electrode and a second channel part not overlapping the gate electrode.

### CROSS-REFERENCE TO RELATED APPLICATIONS

This application claims the benefit of priority of the Korean Patent Application No. 10-2022-0188532 filed on Dec. 29, 2022, which is hereby incorporated by reference as if fully set forth herein.

### BACKGROUND

### Technical Field

The present disclosure relates to a thin film transistor and a display apparatus including the same. More specifically, one embodiment of the present disclosure relates to a thin film transistor having an improved s-factor characteristics and an improved current characteristics, and a display device including the same.

### Description of the Related Art

Since a thin film transistor may be manufactured on a glass substrate or a plastic substrate, the thin film transistor has been widely used as a switching element or a driving element of a display device such as a liquid crystal display device or an organic light emitting device.

The thin film transistor may be categorized into an amorphous silicon thin film transistor in which amorphous silicon is used as an active layer, a polycrystalline silicon thin film transistor in which polycrystalline silicon is used as an active layer, and an oxide semiconductor thin film transistor in which oxide semiconductor is used as an active layer, based on a material constituting the active layer.

Among them, the oxide semiconductor thin film transistor (Oxide semiconductor TFT) has the advantage of being able to easily obtain the desired physical properties because it has high mobility and can have a large resistance change depending on the oxygen content. Further, since an oxide constituting an active layer may be grown at a relatively low temperature during a process of manufacturing the oxide semiconductor thin film transistor, the manufacturing cost of the oxide semiconductor thin film transistor is reduced. In addition, since an oxide semiconductor is transparent, it is favorable to embody a transparent display.

The display apparatus may include a switching thin film transistor and a driving thin film transistor. Among them, it is advantageous for the driving thin film transistor to have a large s-factor for gray scale expression.

### BRIEF SUMMARY

However, the inventors have realized that it is common for thin film transistors to have small s-factors to secure on-off characteristics. Therefore, when these thin film transistors are applied to the driving thin film transistor of the display apparatus, it is difficult to express a gray scale. Further, it is beneficial for thin film transistors applied to driving thin film transistors of display apparatus to have large s-factor properties to easily express gray scales. In addition, even if the thin film transistor has a large s-factor, it is beneficial to have an improved current characteristics in the ON state.

The present disclosure has been made in view of the various technical problems of the related are including the above identified problems.

Various embodiments of the present disclosure provide a thin film transistor having a large s-factor and an improved current characteristics.

Various embodiments of the present disclosure provide a thin film transistor capable of having a large s-factor, as a part of a channel portion is designed to be driven by a fringing electrical field generated by a gate electrode.

Various embodiments of the present disclosure provide a display apparatus with an improved gray scale expression and an improved current characteristics by using a thin film transistor with a large s-factor and large on-current characteristics as a driving transistor.

In addition to the objects technical benefits the present disclosure as mentioned above, additional benefits and features of the present disclosure will be clearly understood by those skilled in the art from the following description of the present disclosure.

In accordance with an aspect of the present disclosure, a thin film transistor is provided. The thin film transistor includes an active layer and a gate electrode that partially overlaps the active layer. The active layer includes a channel portion, a first connection portion contacting one side, namely a first side of the channel portion and a second connection portion spaced apart from the first connection portion and contacting the other side, namely a second side of the channel portion. The channel portion includes a first channel part overlapping the gate electrode and a second channel part not overlapping the gate electrode. The active layer includes a first active layer and a second active layer on the first active layer. The second active layer includes a material having greater mobility than the first active layer, the first channel part includes the first active layer and the second active layer, the second channel part includes the first active layer.

The second channel part may be configured to be driven by a fringing electric field generated by a gate electrode.

The active layer is an oxide semiconductor layer including an oxide semiconductor material, and each of the first connection portion and the second connection portion may be formed by selective conductorization of the oxide semiconductor layer.

The first channel part and the second channel part are non-conductorized parts of the active layer.

Each of the first channel part and the second channel part may extend from the first connection portion to the second connection portion.

The second channel part may be parallel to the longitudinal direction of the channel portion. Here, the longitudinal direction of the channel portion may be defined as a direction parallel to a direction connecting the first connection portion and the second connection portion.

A width of the second channel part may be in a range of 10% to 50% with respect to the width of the channel portion. The width of the second channel part may be defined as a distance between both ends of the second channel part measured in a direction perpendicular to a length direction of the channel portion.

An area of the second active layer disposed in the second channel part may be in a range of 50% or less with respect to a total area of the second channel part.

The second active layer may not be disposed on the second channel part.

An area of the second active layer disposed in the first channel part may be in a range of 90% or more with respect to the total area of the first channel part.

The second active layer may be disposed in the entire region of the first channel part, in a plan view.

The active layer may further include a third active layer on the second active layer, and at least a part of the third active layer may be disposed in the first channel part.

The third active layer may not be disposed in the second channel part.

The third active layer may be disposed in both the first channel part and the second channel part.

The first active layer may include a first oxide semiconductor layer and a second oxide semiconductor layer on the first oxide semiconductor layer.

The gate electrode may include a plurality of protrusion parts spaced apart from each other in a plan view, and the second channel part may be disposed between the protrusion parts adjacent to each other.

The plurality of protrusion parts may protrude in a width direction of the channel portion, and a width direction of the channel portion may be defined in a direction perpendicular to a direction connecting the first connection portion and the second connection portion.

In accordance with other aspect of the present disclosure, the above and other objects can be accomplished by the provision of a method for manufacturing a thin film transistor, which comprises forming an active layer on a substrate, forming a gate insulating layer on the active layer, forming a gate material layer on the gate insulating layer, forming a photoresist pattern on the gate material layer, forming a gate electrode by etching the gate material layer using the photoresist pattern as a mask, selectively conductorizing the active layer, removing a part of the photoresist pattern so that a part of the gate electrode is exposed from the photoresist pattern, and removing a part of the gate electrode exposed from the photoresist pattern.

In selectively conductorizing the active layer, a part of the active layers may not be conductorized and becomes a channel portion, and in removing the part of the gate electrode, a part of the gate electrode overlapping the channel portion may be removed.

Another embodiment of the present disclosure includes a pixel driving circuit and a display element connected to the pixel driving circuit, wherein the pixel driving circuit includes the thin film transistor.

The thin film transistor may be a driving transistor.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a plan view of a thin film transistor according to an embodiment of the present disclosure.

FIG. 2A is a cross-sectional view taken along line I-I′ of FIG. 1.

FIG. 2B is a cross-sectional view taken along line II-II′ of FIG. 1.

FIGS. 3A and 3B are schematic diagrams for explaining a fringing electric field Fr, respectively.

FIG. 3C is a schematic diagram illustrating an electric field applied to an active layer.

FIG. 4 is a graph illustrating drain-source current with respect to gate voltages applied to thin film transistors.

FIG. 5 is a graph illustrating a drain-source current with respect to a gate voltage applied to thin film transistors according to test examples.

FIG. 6 is a cross-sectional view of a thin film transistor according to another embodiment of the present disclosure.

FIG. 7 is a plan view of a thin film transistor according to another embodiment of the present disclosure.

FIG. 8 is a cross-sectional view taken along line III-III′ of FIG. 7.

FIG. 9 is a cross-sectional view of a thin film transistor according to another embodiment of the present disclosure.

FIG. 10 is a cross-sectional view of a thin film transistor according to another embodiment of the present disclosure.

FIG. 11 is a cross-sectional view of a thin film transistor according to another embodiment of the present disclosure.

FIGS. 12A and 12B are plan views of a thin film transistor according to another embodiment of the present disclosure, respectively.

FIGS. 13A to 13H are schematic diagrams illustrating a method of manufacturing a thin film transistor according to an embodiment of the present disclosure.

FIG. 14 is a schematic view of a display apparatus according to another embodiment of the present disclosure.

FIG. 15 is a circuit diagram of one pixel of FIG. 14.

FIG. 16 is a plan view of a pixel of FIG. 15.

FIG. 17 is a cross-sectional view taken along line IV-IV′ of FIG. 16.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art.

A shape, a size, a dimension (e.g., length, width, height, thickness, radius, diameter, area, etc.), a ratio, an angle and a number of elements disclosed in the drawings for describing embodiments of the present disclosure are merely an example and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted.

In a case where ‘comprise,’ ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜,’ ‘above˜,’ ‘below˜’ and ‘next to˜,’ one or more portions may be disposed between two other portions unless ‘just’ or ‘direct’ is used.

Spatially relative terms such as “below,” “beneath,” “lower,” “above,” and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below,” or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first.” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

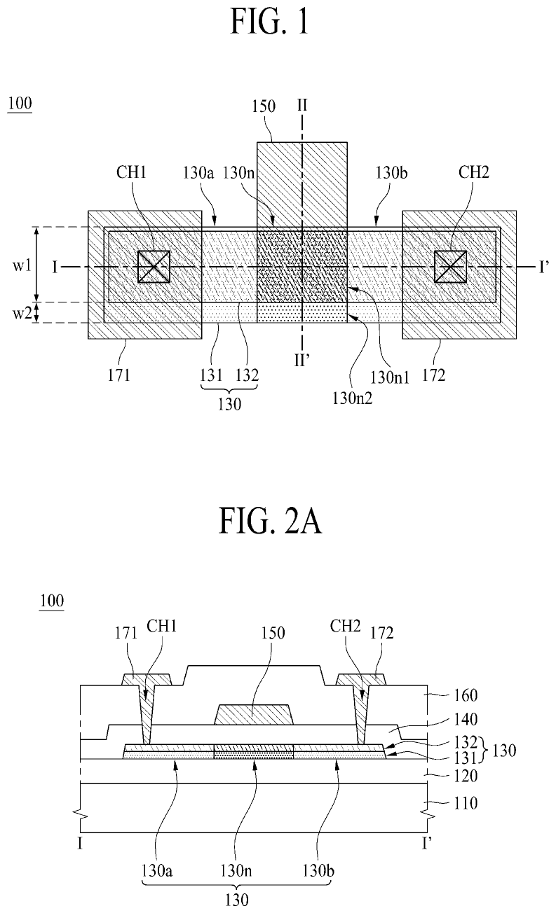

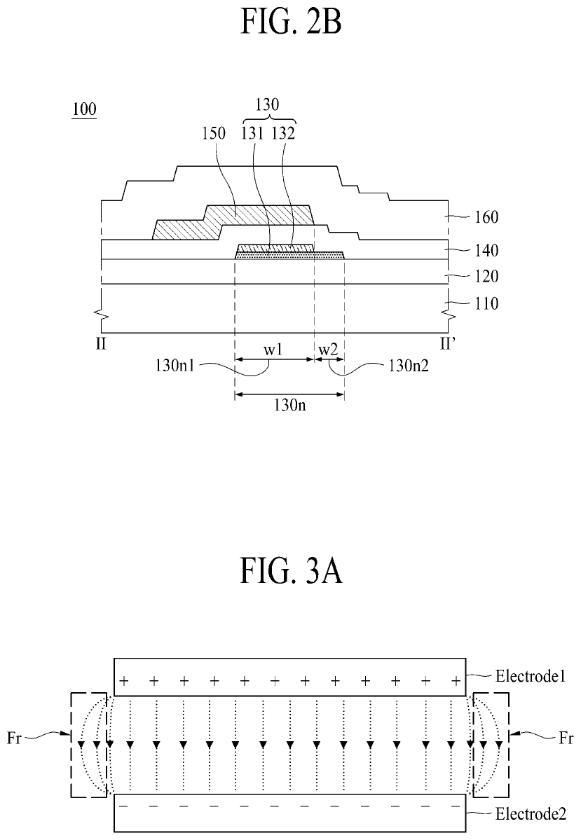

FIG. 1 is a plan view of a thin film transistor 100 according to an embodiment of the present disclosure, FIG. 2A is a cross-sectional view taken along I-I′ of FIG. 1, and FIG. 2B is a cross-sectional view taken along II-II′ of FIG. 1.

Referring to FIGS. 1, 2A, and 2B, the thin film transistor 100 according to an embodiment of the present disclosure includes an active layer 130 and a gate electrode 150 that partially overlaps the active layer 130. The active layer 130 includes a first active layer 131 and a second active layer 132.

Referring to FIG. 2A, a thin film transistor 100 according to an embodiment of the present disclosure is disposed on the substrate 110.

Glass or plastic may be used as the substrate 110. Transparent plastic having flexible properties as plastic, for example, polyimide, may be used. When polyimide is used as a substrate 110, heat-resistant polyimide that can withstand high temperatures may be used considering that a high-temperature deposition process is performed on the substrate 110.

Referring to FIGS. 2A and 2B, a buffer layer 120 may be disposed on the substrate 110. The buffer layer 120 protects the active layer 130. The surface of the upper part of the substrate 110 may be uniform by the buffer layer 120.

The active layer 130 is disposed on the substrate 110. Referring to FIGS. 2A and 2B, the active layer 130 may be disposed on the buffer layer 120.

The active layer 130 may include a semiconductor material. According to an embodiment of the present disclosure, the active layer 130 may include an oxide semiconductor material.

According to an embodiment of the present disclosure, the active layer 130 may include a first active layer 131 and a second active layer 132. In addition, the active layer 130 may include a channel portion 130n, a first connection portion 130a, and a second connection portion 130b.

Detailed descriptions of the first active layer 131, the second active layer 132, and the channel portion 130n will be described later.

A gate insulating layer 140 is disposed on the active layer 130. The gate insulating layer 140 protects the channel portion 130n.

The gate insulating layer 140 may include at least one of silicon oxide, silicon nitride, and metal-based oxide. The gate insulating layer 140 may have a single layer structure or a multilayer layer structure.

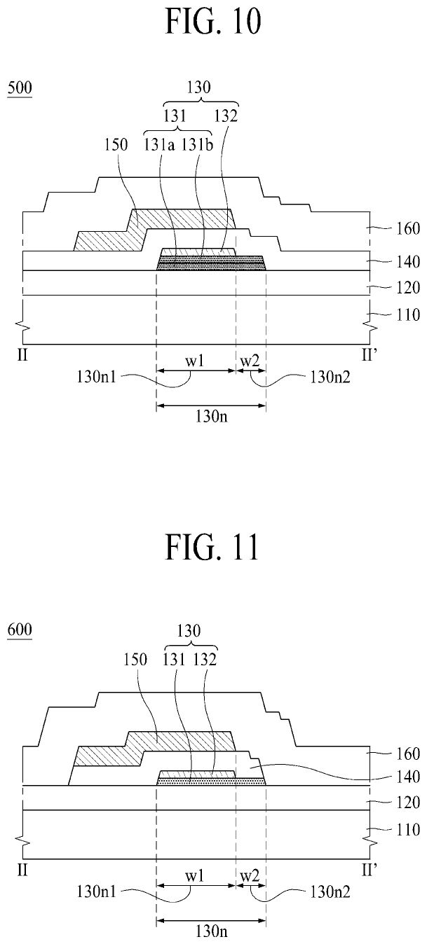

Referring to FIGS. 2A and 2B, the gate insulating layer 140 may not be separately patterned but may be disposed on the entire surface of the substrate 110. However, one embodiment of the present disclosure is not limited thereto, and the gate insulating layer 140 may have a patterned structure (see FIG. 10).

The gate electrode 150 is disposed on the gate insulating layer 140. The gate electrode 150 overlaps at least a part of the active layer 130. According to an embodiment of the present disclosure, the gate electrode 150 overlaps the first channel part 130n1 of the active layer 130.

The gate electrode 150 may include at least one of aluminum-based metals such as aluminum (Al) or aluminum alloys, silver-based metals such as silver (Ag) or silver alloys, copper-based metals such as copper (Cu) or copper alloys, molybdenum-based metals such as molybdenum (Mo) or molybdenum alloys, chromium (Cr), tantalum (Ta), neodymium (Nd), and titanium (Ti). Each of the gate electrodes 150 may have a multilayer structure including at least two conductive layers having different physical properties.

Referring to FIGS. 2A and 2B, an interlayer insulating layer 160 may be disposed on the gate electrode 150. The interlayer insulating layer 160 may be made of an organic or inorganic insulating material. The interlayer insulating layer 160 may be formed of a composite layer of an organic layer and an inorganic layer.

The thin film transistor 100 according to an embodiment of the present disclosure may include a source electrode 171 and a drain electrode 172 disposed on the interlayer insulating layer 160. The source electrode 171 and the drain electrode 172 may be connected to the active layer 130 through contact holes CH1 and CH2, respectively. Specifically, the source electrode 171 may contact the first connection portion 130a through the contact hole CH1. The drain electrode 172 may be spaced apart from the source electrode 171 and may be in contact with the second connection portion 130b through the contact hole CH2.

The thin film transistor 100 according to an embodiment of the present disclosure may be constructed by the active layer 130, the gate electrode 150, the source electrode 171, and the drain electrode 172.

Hereinafter, the active layer 130 and the channel portion 130n of the thin film transistor 100 according to an embodiment of the present disclosure will be described in more detail.

According to an embodiment of the present disclosure, the active layer 130 includes a channel portion 130n, a first connection portion 130a, and a second connection portion 130b. The first connection portion 130a contacts one side, namely a first side, of the channel portion 130n, and the second connection portion 130b is separated from the first connection portion 130a and contacts the other side, namely a second side, of the channel portion 130n. The channel portion 130n connects the first connection portion 130a and the second connection portion 130b between the first connection portion 130a and the second connection portion 130b.

The first connection portion 130a and the second connection portion 130b may be formed by selectively conductorizing the active layer 130. According to an embodiment of the present disclosure, the active layer 130 is an oxide semiconductor layer including an oxide semiconductor material, and the first connection portion 130a and the second connection portion 130b may be formed by selective conductorization of the oxide semiconductor layer.

According to an embodiment of the present disclosure, the process of imparting conductivity to the oxide semiconductor layer is called conductorization, and the process of imparting conductivity to a specific region selected from the oxide semiconductor layer is called selective conductorization. A portion to which conductivity is imparted by selective conductorization is conductorized, and a portion to which conductivity is not imparted is not conductorized.

According to an embodiment of the present disclosure, selective conductorization may be performed by doping or plasma treatment using a dopant.

For example, selective conductorization of the active layer 130 can be achieved by dopant doping using a gate electrode 150, a metal layer, or a photoresist pattern as a mask. In accordance with an embodiment of this disclosure, injecting a dopant or dopant ion into a selected region of the active layer 130 is called dopant doping. The dopant may include, for example, at least one of boron (B), phosphorus (P), fluorine (F), and hydrogen (H).

When selective conductorization of the active layer 130 is performed by dopant doping, the dopant-doped area of the active layer 130 is selectively conductorized to form the first connection portion 130a or the second connection portion 130b. A region of the active layer 130 that is not doped with a dopant may not be conductorized and may become the channel portion 130n.

In addition, selective conductorization of the active layer 130 may be achieved by plasma treatment applied to the process of patterning the gate insulating layer 140. For example, plasma may be used in the process of patterning the gate insulating layer 140, and the part of the active layer 130 in contact with the plasma may be selectively conductorized to become the first connection portion 130a or the second connection portion 130b. A portion of the active layer 130 that is protected by the gate insulating layer 140 and does not come into contact with plasma is not conductorized and may become a channel portion 130n.

According to an embodiment of the present disclosure, the first connection portion 130a and the second connection portion 130b are also referred to as conductorized portions. According to an embodiment of the present disclosure, the first connection portion 130a of the active layer 130 may be a source region, and the second connection portion 130b may be a drain region. However, one embodiment of this disclosure is not limited to this, and the first connection portion 130a may be a drain part, and the second connection portion 130b may be a source part.

According to an embodiment of the present disclosure, the channel portion 130n includes a first channel part 130n1 and a second channel part 130n2. A portion of the active layer 130 that is not conductorized may be a first channel part 130n1 and a second channel part 130n2. The first channel part 130n1 and the second channel part 130n2 are made of an oxide semiconductor material, but are not conductorized, and since they are placed between the first connection portion 130a and the second connection portion 130b, they can serve as a channel of the thin film transistor 100.

The first channel part 130n1 and the second channel part 130n2 may be determined by whether to overlap the gate electrode 150.

According to an embodiment of the present disclosure, the first channel part 130n1 overlaps the gate electrode 150, and the second channel part 130n2 does not overlap the gate electrode 150. More specifically, a portion of the channel portion 130n that overlaps the gate electrode 150 may be defined as the first channel part 130n1, and a portion of the channel portion 130n that does not overlap the gate electrode 150 may be defined as the second channel part 130n2.

According to an embodiment of the present disclosure, all regions of the first channel part 130n1 may overlap the gate electrode 150. Since the first channel part 130n1 overlaps the gate electrode 150, it is directly affected by the electric field generated by the gate electrode 150. The first channel part 130n1 is driven by an electric field generated by the gate electrode 150.

Since the second channel part 130n2 does not overlap the gate electrode 150, it may be driven by a fringing electric field generated by the gate electrode 150.

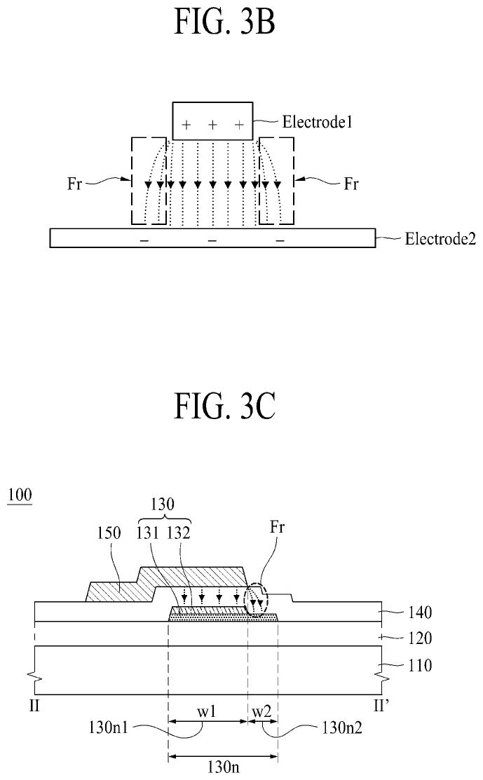

FIGS. 3A and 3B are schematic diagrams for explaining a fringing electric field Fr, respectively. The arrows in FIGS. 3A and 3B indicate an electric field. The direction of the arrow is not limited by FIGS. 3A and 3B, and the direction of the arrow may be opposite to the direction disclosed in FIGS. 3A and 3B.

Referring to FIG. 3A, a uniform electric field is formed in a region where two electrodes (Electrode 1 and Electrode 2) overlap. On the other hand, a non-uniform electric field is formed in the outer space of the region where the two electrodes (Electrode 1 and Electrode 2) overlap. As such, a non-uniform electric field formed by extending to the outer space of a region where two electrodes (Electrode 1 and Electrode 2) overlap is called a fringing electric field Fr.

Referring to FIG. 3B, an electric field can be formed between two electrodes (Electrode 1 and Electrode 2) with different areas. In FIG. 3B, a uniform electric field is formed in a region where the two electrodes 1 and 2 overlap. On the other hand, a non-uniform electric field is formed in an outer space of a region where two electrodes (Electrode 1 and Electrode 2) overlap, and the electric field thus formed may be referred to as a fringed electric field.

According to an embodiment of this disclosure, a non-uniform electric field formed by extending from an edge of any one electrode (Electrode 1) to an outer space of a region where two electrodes (Electrode 1 and Electrode 2) overlap is called a fringed electric field Fr.

In terms of electric field formation, the gate electrode 150 and the active layer 130 of the thin film transistor 100 according to an embodiment of this disclosure may correspond to the electrodes 1 and 2 illustrated in FIGS. 3A and 3B, respectively. According to one embodiment of this disclosure, the electric field formed by extending to the outer space of a region where the gate electrode 150 and the active layer 130 overlap is called the fringed electric field Fr. According to an embodiment of this disclosure, the fringed electric field can be formed by extending from the edge of the gate electrode 150 to the outer space of a region where the gate electrode 150 and the active layer 130 overlap.

According to an embodiment of the present disclosure, when a gate voltage is applied to the gate electrode 150, a uniform electric field may be applied to the first channel part 130n1 overlapping the gate electrode 150. On the other hand, a fringed electric field Fr is applied to the second channel part 130n2 that does not overlap the gate electrode 150.

FIG. 3C is a schematic diagram illustrating an electric field applied to the active layer 130.

In FIG. 3C, an arrow indicates an electric field. The direction of the arrow is not limited by FIG. 3C, and the direction of the arrow may be opposite to the direction disclosed in FIG. 3C.

Referring to FIG. 3C, it may be seen that a fringed electric field Fr is applied to the second channel part 130n2 that does not overlap the gate electrode 150.

The strength of the fringed electric field is weaker than that of the uniform electric field generated in the area where the gate electrode 150 and the active layer 130 overlap. Therefore, when a gate voltage is applied to the gate electrode 150, an electric field weaker than that of the first channel part 130n2 is applied to the second channel part 130n2.

Since an electric field weaker than that of the first channel part 130n1 is applied to the second channel part 130n2, when the gate voltage applied to the gate electrode 150 increases, the amount of current passing through the second channel part 130n2 is less than the amount of current passing through the first channel part 130n1. As a result, when the gate voltage applied to the gate electrode 150 increases, the increase rate of the current passing through the second channel part 130n2 is less than the increase rate of the current passing through the first channel part 130n1.

In this way, when a gate voltage is applied to the gate electrode 150, the second channel part 130n2 may play a role of delaying the current increase rate of the channel portion 130n. As a result, the s-factor of the thin film transistor 100 may be increased due to the second channel part 130n2.

The sub-threshold swing (s-factor) can be used as an indicator of the degree of change in the drain-source current (Drain-Source Current) to the gate voltage (Gate Voltage) of the thin film transistor 100.

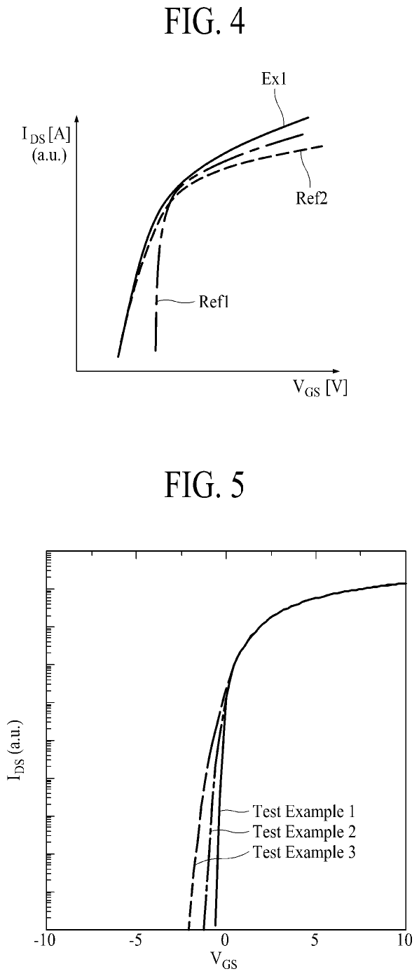

The s-factor may be described, for example, by a drain-source current graph illustrated in FIG. 4.

FIG. 4 is a graph illustrating drain-source current I_{DS} with respect to a gate voltage VGS applied to a thin film transistor, respectively. When the thin film transistor is turned on, the reciprocal of the drain-source current I_{DS} graph slope (sub-threshold slope) to the gate voltage VGS can be defined as an s-factor. If the slope of the graph is steep, the s-factor is small, and if the slope of the graph is small, the s-factor is large. When the s-factor is large, when the thin film transistor is turned on, the change rate of the drain-source current I_{DS} with respect to the gate voltage is gentle.

When the s-factor is large, the change rate of the drain-source current I_{DS} to the gate voltage is gentle, so it is easy to control the size of the drain-source current I_{DS} by adjusting the gate voltage VGS.

In a display apparatus driven by current, for example, an organic light emitting display apparatus, the gradation of a pixel can be controlled by adjusting the size of the drain-source current I_{DS} of the driving thin film transistor. The magnitude of the drain-source current I_{DS} of the driving thin film transistor is determined by the gate voltage. Therefore, in an organic light emitting display apparatus driven by current, the larger the s-factor of the driving thin film transistor (Driving TR), the easier it is to adjust the gray scale of the pixel. The thin film transistor 100 according to an embodiment of this disclosure having a large s-factor can be used as a driving thin film transistor (Driving TR) of an organic light emitting display apparatus.

According to an embodiment of the present disclosure, the active layer 130 includes a first active layer 131 and a second active layer 132 on the first active layer 131. The second active layer 132 may include a material having a greater mobility than that of the first active layer 131. For example, the second active layer 132 may be made of a material having a greater mobility than that of the first active layer 131. In an embodiment of the present disclosure, a mobility means a carrier mobility.

For example, the second active layer 132 may have a mobility twice or more than that of the first active layer 131. More specifically, the second active layer 132 may have mobility twice to five times that of the first active layer 131.

The first active layer 131 may include a low mobility oxide semiconductor material. In detail, the first active layer 131 may be made of a low mobility oxide semiconductor material. For example, the first active layer 131 may include a gallium (Ga)-based oxide semiconductor material. The first active layer 131 including the gallium (Ga)-based oxide semiconductor material has relatively low mobility and may have a stable film structure.

According to an embodiment of this disclosure, the first active layer 131 may include at least one of an IGZO (InGaZnO)-based oxide semiconductor material, a GZO (GaZnO)-based oxide semiconductor material, an IGO (InGaO)-based oxide semiconductor material, and a GZTO (GaZnSnO)-based oxide semiconductor material. However, one embodiment of this disclosure is not limited to this, and the first active layer 131 may be formed by other low-mobility oxide semiconductor materials known in the art. When the oxide semiconductor material constituting the first active layer 131 contains gallium (Ga) and indium (In), the concentration of gallium (Ga) is set higher than the concentration of indium (In) based on the number of moles (Ga concentration>In concentration).

Specifically, indium In is known as an element that improves mobility of the semiconductor layer or the active layer 130. Therefore, when the first active layer 131 includes indium (In), the content of indium (In) may be set to be smaller than the content of gallium (Ga) based on the number of moles.

The second active layer 132 may be made of a highly mobile oxide semiconductor material. For example, the second active layer 132 may include an indium (In)-based or zinc (Zn)-based oxide semiconductor material.

According to an embodiment of the present disclosure, the second active layer 132 may include at least one of an IGZO (InGaZnO)-based oxide semiconductor material, an IZO (InZnO)-based oxide semiconductor material, an IGZTO (InGaZnSnO)-based oxide semiconductor material, an ITZO (InSnZnO)-based oxide semiconductor material, a FIZO (FeInZnO)-based oxide semiconductor material, a ZO (ZnO)-based oxide semiconductor material, an SIZO (SnInZnO)-based oxide semiconductor material, an ZnON (Zn-Oxynitride)-based oxide semiconductor material. When the oxide semiconductor material constituting the second active layer 132 contains gallium (Ga) and indium (In), the concentration of indium (In) is set higher than the concentration of gallium (Ga) based on the number of moles (mole).

Specifically, gallium Ga may decrease mobility of the oxide semiconductor. Therefore, when the second active layer 132 includes gallium (Ga), the content of gallium (Ga) may be set to be smaller than the content of indium (In) based on the number of moles.

According to an embodiment of the present disclosure, the first active layer 131 may have a mobility of 5 to 25 cm2/V·s. More specifically, the first active layer 131 may have a mobility of 5 to 15 cm2/V·s, and may have a mobility of about 10 cm2/V·s.

The second active layer 132 may have a mobility of 20 cm2/V·s or more. Specifically, the second active layer 132 may have a mobility of about 20 to 50 cm2/V·s. More specifically, the second active layer 132 may have mobility in the range of 20 to 40 cm2/V·s, or 20 to 30 cm2/V·s.

According to an embodiment of the present disclosure, the second active layer 132 may have a greater mobility by 10 to 40 cm2/V·s than the first active layer 131. Compared to the first active layer 131, the second active layer 132 may have greater mobility by 10 to 30 cm2/V·s, greater mobility by 10 to 20 cm2/V·s, or greater mobility by 20 to 30 cm2/V·s.

According to an embodiment of this disclosure, the first active layer 131 and the second active layer 132 constituting the active layer 130 are oxide semiconductor layers including oxide semiconductor materials, respectively, and the first connection portion 130a and the second connection portion 130b may be formed by selective conductorization of the first active layer 131 and the second active layer 132.

The first channel part 130n1 may include a first active layer 131 and a second active layer 132, and the second channel part 130n2 may include a first active layer 131.

Since the first channel part 130n1 includes the second active layer 132 with high mobility, it can serve to increase the on-current of the thin film transistor 100. More specifically, the second active layer 132 may be disposed on the first active layer 131 and may serve as a main channel layer. Since the second active layer 132 has high mobility, current flows smoothly through the first channel part 130n1 and the on-current characteristics of the thin film transistor 100 can be improved.

The second channel part 130n2 includes a first active layer 131 having a relatively low mobility. Due to the first active layer 131 with low mobility, when a gate voltage is applied to the gate electrode 150, the increase in current in the channel portion 130n may be delayed. In particular, if the second active layer 132 is not disposed in the second channel part 130n2 and only the first active layer 131 is disposed, the effect of delaying the increase in current in the second channel part 130n2 may increase. In addition, as described above, a relatively weak fringed electric field Fr is applied to the second channel part 130n2. As a result, the delay effect of increasing the current of the channel portion 130n by the second channel part 130n2 may be increased.

As such, the s-factor of the thin film transistor 100 may be greatly increased by the second channel part 130n2 including the first active layer 131 and receiving only the effect of the fringed electric field Fr.

Referring to FIGS. 1 and 2B, the first active layer 131 may have a width greater than that of the second active layer 132. The second active layer 132 may be disposed only on a part of the first active layer 131. According to an embodiment of the present disclosure, the second active layer 132 may be designed not to be disposed on the second channel part 130n2. In this case, since only the first active layer 131 with low mobility is disposed in the second channel part 130n2 that receives only the effect of the fringed electric field Fr, the current increase delay effect of the channel portion 130n can be increased, and the s-factor of the thin film transistor 100 can be greatly increased.

In addition, the second active layer 132 may be disposed in the entire region of the first channel part 130n1. In this case, the second active layer 132 with high mobility in the first channel part 130n1 may cover the entire upper surface of the first active layer 131, and the second active layer 132 may serve as a main channel in the entire area of the first channel part 130n1. As a result, the on-current increase effect of the thin film transistor 100 may increase.

A part of the second active layer 132 may be disposed on the second channel part 130n2 due to an error in the manufacturing process or design reasons. However, even in this case, to prevent the increase in mobility of the second channel part 130n2 by the second active layer 132, the area of the second active layer 132 disposed on the second channel part 130n2 may be designed to be in a range of 50% or less with respect to the total area of the second channel part 130n2. When the area of the second active layer 132 disposed in the second channel part 130n2 exceeds 50% with respect to the total area of the second channel part 130n2, the mobility of the second channel part 130n2 may increase more than necessary due to the second active layer 132, and the effect of greatly increasing the s-factor of the thin film transistor 100 may be reduced.

More specifically, the area of the second active layer 132 disposed in the second channel part 130n2 may be designed to be in a range of 30% or less with respect to the total area of the second channel part 130n2, or may be designed to be in a range of 10% or less, or 0 to 5% with respect to the total area of the second channel part 130n2.

In addition, the second active layer 132 may not cover the entire area of the first channel part 130n1 due to errors in the manufacturing process or design reasons. However, even in this case, the second active layer 132 is designed to cover 90% or more of the total area of the first channel part 130n1 in order to maintain the high mobility characteristics and high current characteristics of the first channel part 130n1. When the second active layer 132 occupies less than 90% of the total area of the first channel part 130n1, the on-current of the thin film transistor 100 may be reduced.

More specifically, the area of the second active layer 132 disposed in the first channel part 130n1 may be designed to be in a range of 95 to 100% with respect to the total area of the first channel part 130n1.

Referring to FIG. 1, the first channel part 130n1 and the second channel part 130n2 may extend from the first connection portion 131 to the second connection portion 132, respectively. As a result, the channel portion 130 including the first channel part 130n1 and the second channel part 130n2 may effectively serve as a channel of the thin film transistor 100. In addition, the same effect may occur as one thin film transistor by the first channel part 130n1 and another thin film transistor by the second channel part 130n2 are arranged in parallel. More specifically, according to an embodiment of this disclosure, a thin film transistor 100 such as a high current thin film transistor including a first channel part 130n1 and a low current thin film transistor including a second channel part 130n2 are arranged in parallel.

According to an embodiment of the present disclosure, the second channel part 130n2 may be made parallel to the longitudinal direction of the channel portion 130n. According to an embodiment of this disclosure, the longitudinal direction of the channel portion 130n is defined as a direction parallel to the direction connecting the first connection portion 130a and the second connection portion 130b. More specifically, the longitudinal direction of the channel portion 130n may be defined as a direction parallel to the direction of the shortest distance connecting the first connection portion 130a and the second connection portion 130b.

In FIG. 1, the horizontal direction of the drawing becomes the length direction of the channel portion 130n, and the vertical direction of the drawing becomes the width direction of the channel portion 130n. The width direction of the channel portion 130n may be defined as a direction perpendicular to the length direction of the channel portion 130n. Referring to FIG. 1, the second channel part 130n2 may have a line shape in a plan view.

The ratio [w2/(w1+w2) of the width (w2) of the second channel part 130n2 to the total width (w1+w2) of the channel portion 130n may vary depending on the type of oxide semiconductor material constituting the first and second active layers 131 and 132, the type of insulating layer, the type of gate insulating layer 140, the dielectric constant of the gate insulating layer 140, the thickness of the gate insulating layer 140, etc.

According to an embodiment of the present disclosure, the width w2 of the second channel part 130n2 may be in a range of 10% to 50% with respect to the width w1+w2 of the channel portion 130n. Here, the width w2 of the second channel part 130n2 is defined as the distance between both ends of the second channel part 130n2 measured along a direction perpendicular to the longitudinal direction of the channel portion 130n.

When the width w2 of the second channel part 130n2 is less than 10% with respect to the width w1+w2 of the channel portion 130n, the on-current of the thin film transistor 100 may increase, but the width w2 of the second channel part 130n2 is narrowed so that the effect of increasing the s-factor by the second channel part 130n2 is reduced, thereby reducing the s-factor of the thin film transistor 100. Accordingly, the width w2 of the second channel part 130n2 may be set to be in a range of 10% or more with respect to the width w1+w2 of the channel portion 130n.

On the other hand, if the width w2 of the second channel part 130n2 exceeds 50% with respect to the width w1+w2 of the channel portion 130n, the s-factor of the thin film transistor 100 may increase, but the off-current of the thin film transistor 100 may increase due to the excessively widened second channel part 130n2. In addition, if the width w2 of the second channel part 130n2 exceeds 50% with respect to the width w1+w2 of the channel portion 130n, a bump phenomenon in which the drain-source current I_{DS} changes in two stages may occur in the drain-source current I_{DS} graph for the gate voltage VGS.

On the other hand, as the distance from the gate electrode 150 increases, the effect of the fringed electric field Fr by the gate electrode 150 may decrease or the effect of the fringed electric field Fr by the gate electrode 150 may not be received. Accordingly, a portion of the second channel part 130n2 far from the gate electrode 150 may not serve as a channel. Specifically, if the width w2 of the second channel part 130n2 exceeds 50% with respect to the width w1+w2 of the channel portion 130n, there may be a part that cannot function as a channel because it is far away from the gate electrode 150. Accordingly, when the width w2 of the second channel part 130n2 exceeds 50% with respect to the width w1+w2 of the channel portion 130n, unnecessary space waste may occur.

In consideration of the above descriptions, according to an embodiment of the present disclosure, the width w2 of the second channel part 130n2 may be set in a range of 50% or less with respect to the width w1+w2 of the channel portion 130n. More specifically, the width w2 of the second channel part 130n2 may be set to be in a range of 30% or less with respect to the width w1+w2 of the channel portion 130n, and the width w2 of the second channel part 130n2 may be set to be in a range of 10% to 30% with respect to the width w1+w2 of the channel portion 130n.

As described above, the thin film transistor 100 according to an embodiment of this disclosure may have a large on-current and a large s-factor at the same time. Therefore, the thin film transistor 100 according to an embodiment of this disclosure is used as a driving thin film transistor (Driving TR) of a display apparatus, which can facilitate the display's gradation expression and improve the display's current characteristics.

FIG. 4 is a graph illustrating drain-source current with respect to gate voltages applied to thin film transistors.

In FIG. 4, the graph shown as “Ex 1” is a threshold voltage graph for the thin film transistor 100 of FIG. 1, “Ref 1” is a threshold voltage graph of the thin film transistor that reduces the thickness of the gate insulating layer 140 to improve on-current. “Ref 2” is a threshold voltage graph of a thin film transistor that increases the thickness of the gate insulating film 140 to improve the s-factor.

Referring to “Ref 1” of FIG. 4, in the case of a thin film transistor with a reduced thickness of a gate insulating layer 140, the on-current of the thin film transistor improves, but the s-factor decreases. Referring to “Ref 2” of FIG. 4, it can be seen that when the thickness of the gate insulating layer 140 is increased, the s-factor of the thin film transistor increases, but the on-current decreases.

On the other hand, it can be seen that the thin film transistor 100 of Embodiment 1 according to the present disclosure has a large s-factor and an improved on-current characteristics.

FIG. 5 is a graph illustrating a drain-source current with respect to a gate voltage applied to thin film transistors according to test examples. More specifically, the graph shown in FIG. 5 is a threshold voltage graph according to the width w2 of the second channel part 130n2 in the thin film transistor 100 shown in FIG. 1. In FIG. 5, the graph indicated by “Test Example 1” is a simulation result when the width w2 of the second channel part 130n2 is 0 μm, the graph indicated by “Test Example 2” is a simulation result when the width w2 of the second channel part 130n2 is 1 μm, and the graph indicated by “Test Example 3” is a simulation result when the width w2 of the second channel part 130n2 is 2 μm.

Referring to FIG. 5, as the width (w2) of the second channel part 130n2 increases, the slope of the threshold voltage graph decreases, and thus the s-factor of the thin film transistor increases.

The s-factor measurement results for Test Examples 1 to 3 are shown in Table 1 below.

TABLE 1

| | Test Exam- | Test Exam- | Test Exam- |
|---|---|---|---|
| Division | ple 1 | ple 2 | ple 3 |
| width of the second channel | 0 | 1 | 2 |
| part [μm] | | | |
| s-factor [V/dec.] | 0.15 | 0.27 | 0.50 |

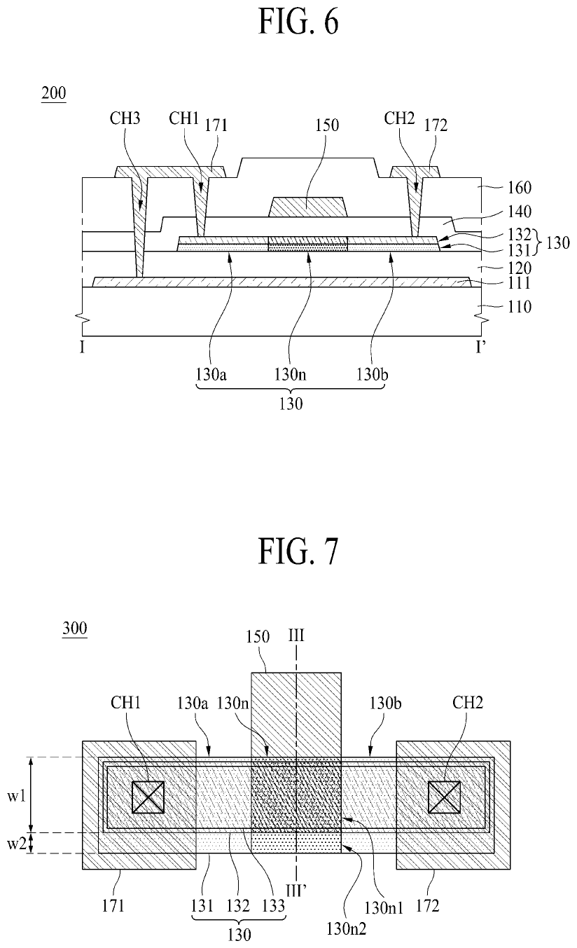

FIG. 6 is a cross-sectional view of a thin film transistor 200 according to another embodiment of the present disclosure. Hereinafter, a description of the components already described in order to avoid overlapping is omitted.

Referring to FIG. 6, a light blocking layer 111 may be disposed on the substrate 110. The light blocking layer 111 may be made of a material having light blocking characteristics. The light blocking layer 111 blocks light incident from the outside to protect the active layer 130. The light blocking layer 111 may be disposed to overlap at least the channel portion 130n of the active layer 130.

The light blocking layer 111 may include a metal and may have electrical conductivity. The light blocking layer 111 may include at least one of aluminum-based metals such as aluminum (Al) or aluminum alloys, silver-based metals such as silver (Ag) or silver alloys, copper-based metals such as copper (Cu) or copper alloys, molybdenum-based metals such as molybdenum (Mo) or molybdenum alloys, chromium (Cr), tantalum (Ta), neodymium (Nd), titanium (Ti), and iron (Fe). The light blocking layer 111 may have a multilayer film structure including at least two conductive layers having different physical properties.

In addition, the source electrode 171 may be connected to the light blocking layer 111 through the contact hole CH3. As a result, the light blocking layer 111 may be electrically connected to the first connection portion 130a of the active layer 130.

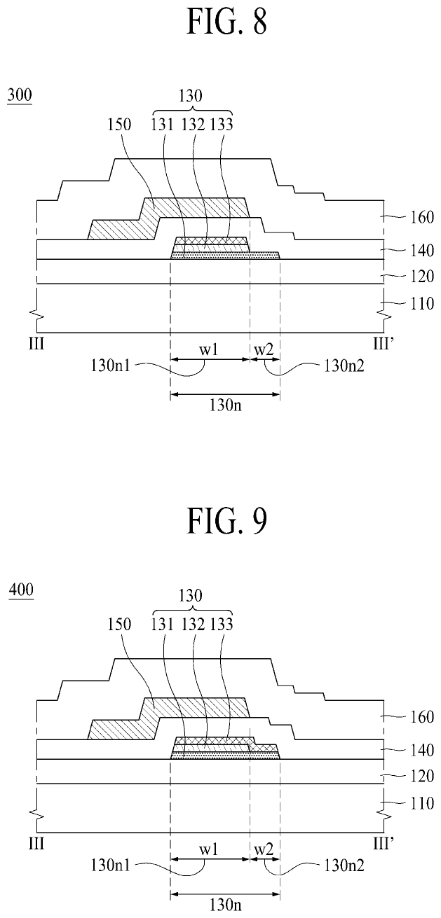

FIG. 7 is a plan view of a thin film transistor 300 according to another embodiment of the present disclosure, and FIG. 8 is a cross-sectional view taken along line III-III′ of FIG. 7.

Referring to FIGS. 7 and 8, the active layer 130 may further include a third active layer 133 on the second active layer 132. The third active layer 133 may be disposed in the channel portion 130n, the first connection portion 130a, and the second connection portion 130b. According to an embodiment of the present disclosure, at least a portion of the third active layer 133 may be disposed on the first channel part 130n1.

The third active layer 133 may protect the second active layer 132. To protect the second active layer 132, the third active layer 133 may be made of an oxide semiconductor material having an improved stability.

The third active layer 133 may include, for example, at least one of an IGZO (InGaZnO)-based oxide semiconductor material [Ga concentration> In concentration], a GZO (GaZnO)-based oxide semiconductor material, an IGO (InGaO)-based oxide semiconductor material, an IGZTO (InGaZnSnO)-based oxide semiconductor material, and a GZTO(GaZnSnO)-based oxide semiconductor material.

When the third active layer 133 is disposed, the second active layer 132, which is an intermediate layer, may be protected during the manufacturing process. For example, in the manufacturing process, the lower first active layer 131 can protect the second active layer 132, which is the intermediate layer, from gas, etc., while the upper third active layer 133 can protect the second active layer 132, which is the intermediate layer, from etching or gas.

Referring to FIG. 8, the third active layer 133 may be disposed to cover the entire upper surface of the second active layer 132. However, one embodiment of this disclosure is not limited to this, and the third active layer 133 may cover a part of the upper surface of the second active layer 132.

Since the third active layer 133 is disposed in the first channel part 130n1, the electron carrier of the first channel part 130n1 may be increased. As a result, the ON-Current of the thin film transistor 100 may be improved. However, the on-current increase effect of the thin film transistor 100 by the third active layer 133 may not be significant.

According to an embodiment of the present disclosure, the third active layer 133 may not be disposed on the second channel part 130n2. As a result, even if the third active layer 133 is disposed, the carrier of the second channel part 130n2 may not increase. As a result, the s-factor of the thin film transistor 300 may be maintained at a high level.

FIG. 9 is a cross-sectional view of a thin film transistor 400 according to another embodiment of the present disclosure.

Referring to FIG. 9, a third active layer 133 may be disposed on both the first channel part 130n1 and the second channel part 130n2. The third active layer 133 may protect the upper surface of the second active layer 132 in the first channel part 130n1, and may protect the upper surface of the first active layer 131 in the second channel part 130n2.

In the thin film transistor 400 of FIG. 9, the third active layer 133 is placed in the second channel part 130n2, but the carrier increase effect by the third active layer 133 is not significant. Accordingly, the s-factor of the thin film transistor 400 may be maintained at a high level.

FIG. 10 is a cross-sectional view of a thin film transistor 500 according to another embodiment of the present disclosure.

Compared to the thin film transistor 100 of FIG. 2B, the first active layer 131 may have a multilayer structure in the thin film transistor 500 of FIG. 10.

Referring to FIG. 10, the first active layer 131 may include a first oxide semiconductor layer 131a and a second oxide semiconductor layer 131b on the first oxide semiconductor layer 131a. Both the first oxide semiconductor layer 131a and the second oxide semiconductor layer 131b may have an improved stability and low mobility characteristics. The first active layer 131 formed of a multilayer may effectively protect the second active layer 132 disposed thereon.

The first oxide semiconductor layer 131a and the second oxide semiconductor layer 131b may include the same semiconductor material or may include different semiconductor materials. The second active layer 132 may also have a multilayer structure. For example, the second active layer 132 may have a structure in which multiple layers made of different oxide semiconductor materials with high mobility characteristics are stacked.

FIG. 11 is a cross-sectional view of a thin film transistor 600 according to another embodiment of the present disclosure.

Compared to the thin film transistor 100 of FIGS. 2A and 2B, the thin film transistor 600 of FIG. 11 may include a patterned gate insulating layer 140. Referring to FIG. 11, the gate insulating layer 140 is patterned to cover all of the channel portions 130n. More specifically, the gate insulating layer 140 covers both the upper surface of the first channel part 130n1 and the upper surface of the second channel part 130n2 to protect the first channel part 130n1 and the second channel part 130n2.

Plasma processing may be performed for patterning of the gate insulating layer 140. By plasma treatment, both the gate insulating layers of the upper part of the first connection portion 130a and the upper part of the second connection portion 130b may be removed. In the process of selectively removing the gate insulating layer 140 using plasma, the active layer 130 is selectively plasma-treated, and as a result, the first connection portion 130a and the second connection portion 130b, which are conductorized areas, can be formed.

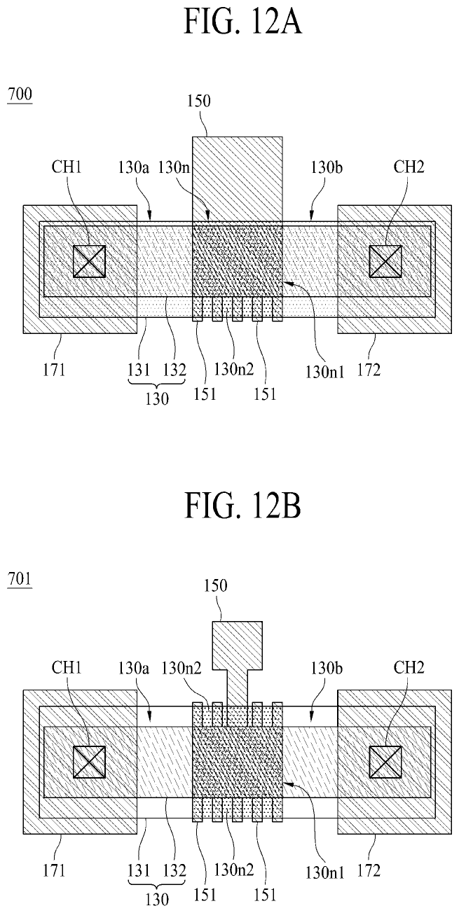

FIGS. 12A and 12B are cross-sectional views of thin film transistors 700 and 701 according to another embodiment of the present disclosure, respectively.

Referring to FIG. 12A, the gate electrodes 150 of the thin film transistor 700 may include a plurality of protrusion parts 151 spaced apart from each other in a plan view. A plurality of protrusion parts 151 may protrude in the width direction of the channel portion 130n. A plurality of protrusion parts 151 protruding along the width direction of the channel portion 130n may be arranged along the length direction of the channel portion 130n.

Due to multiple protrusion parts 151, the gate electrode 150 may have an uneven part formed in the longitudinal direction of the channel portion 130n in a plan view. The protrusion part 151 of the gate electrode 150 may be a convex portion of the uneven portion, and a non-protruding part of the gate electrode 150 may be a concave portion.

The plurality of protrusion parts 151 formed on the gate electrode 150 may protrude out of the area of the first active layer 131 along the width direction of the channel portion 130n. According to another embodiment of the present disclosure, there is no particular limitation on the length of the protrusion. A plurality of protrusion parts 151 may have the same length or may have different lengths. In addition, the plurality of protrusions parts 151 may have the same shape or may have different shapes.

In the thin film transistor 700 of FIG. 12A, the second channel part 130n2 may be disposed between the protrusion parts 151. Referring to FIG. 12, the second channel part 130n2 does not overlap the gate electrode 150. The second channel part 130n2 may be driven by a fringe electric field Fr generated at a corner of the gate electrode 150. In particular, the second channel part 130n2 may be driven by a fringe electric field Fr generated at a corner of the protrusion parts 151.

In the thin film transistor 700 according to another embodiment of this disclosure, the second channel part 130n2 may delay the increase in current in the channel portion 130n when a gate voltage is applied to the gate electrode 150. As a result, the s-factor of the thin film transistor 700 may increase due to the second channel part 130n2.

Referring to FIG. 12B, protrusion parts 151 may be disposed at both sides of the gate electrode 150. More specifically, the protrusion parts 151 may be disposed on both sides of the gate electrode 150 along the width direction of the channel portion 130n.

In the thin film transistor 701 according to another embodiment of the present disclosure, the second channel part 130n2 may be disposed on both sides in the width direction of the channel portion 130n.

When a gate voltage is applied to the gate electrode 150 by the second channel part 130n2 disposed on both sides of the width direction of the channel portion 130n, a delay effect may occur in increasing current in both sides of the width direction of the channel portion 130n. As a result, the s-factor of the thin film transistor 700 may be increased, and the s-factor may be efficiently controlled.

Hereinafter, a method of manufacturing the thin film transistor 100 according to an embodiment of the present disclosure will be described with reference to the drawings.

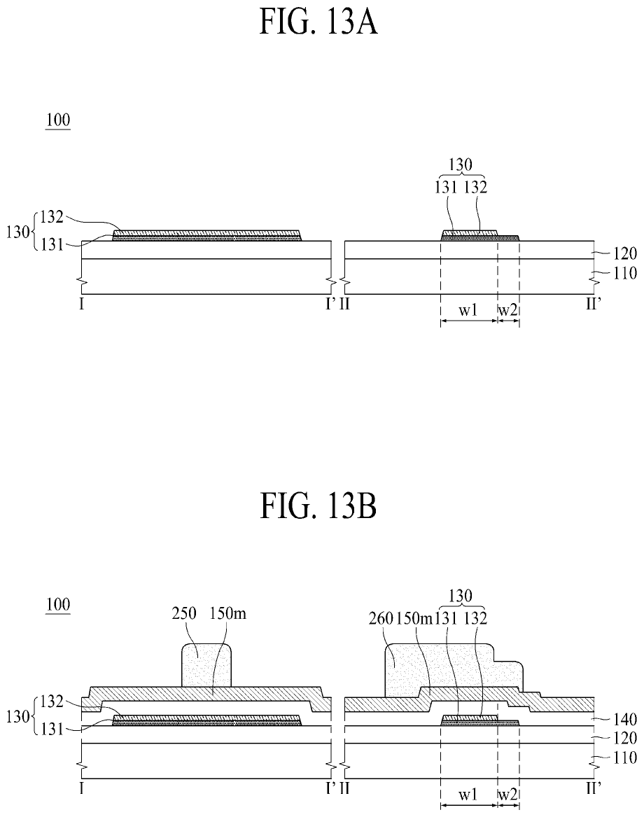

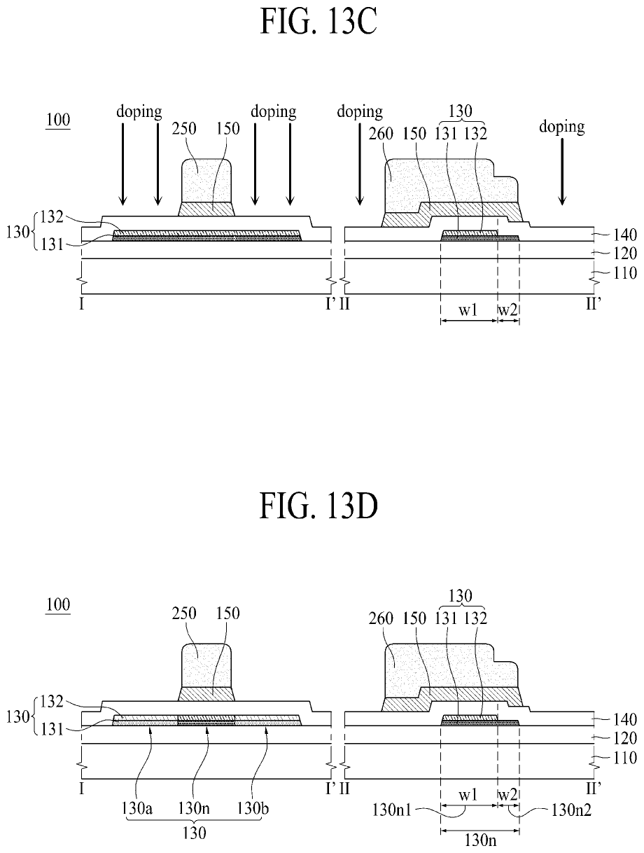

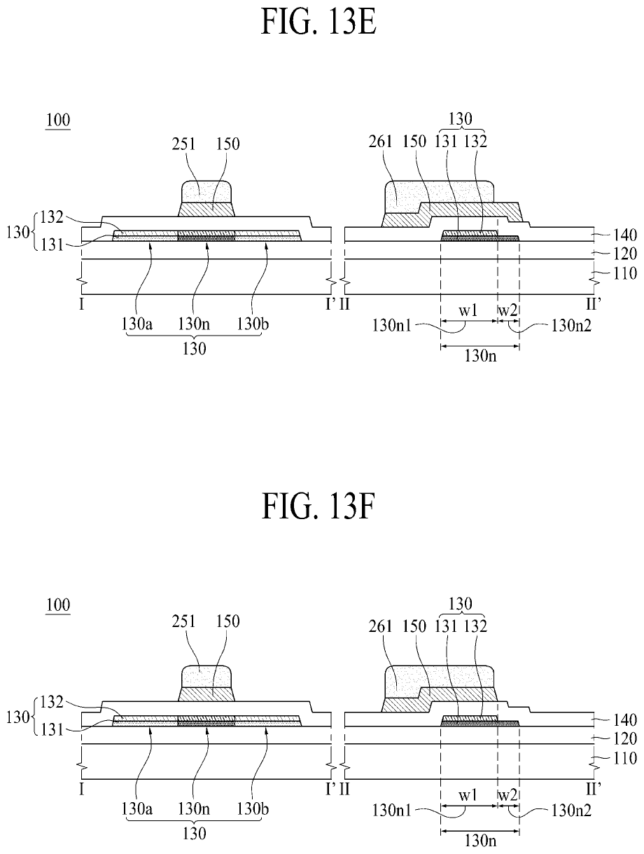

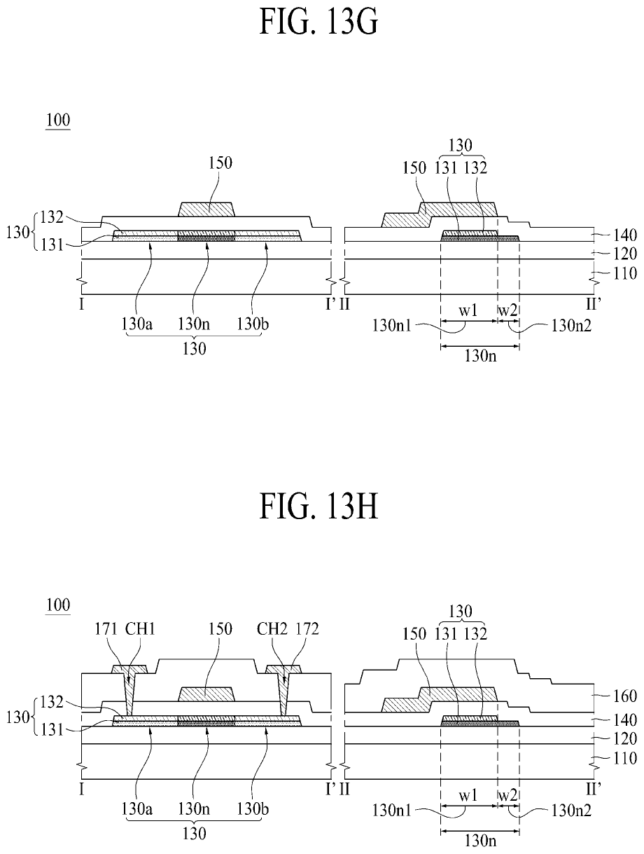

FIGS. 13A to 13H are schematic diagrams illustrating a method of manufacturing a thin film transistor 100 according to an embodiment of the present disclosure. The cross-sectional views illustrated in FIGS. 13A to 13H correspond to cross-sections cut along I-I′ and II-II′ of FIG. 1.

Referring to FIG. 13A, a buffer layer 120 is formed on the substrate 110, and an active layer 130 is formed on the buffer layer 120. The active layer 130 may include a first active layer 131 and a second active layer 132. Each of the first active layer 131 and the second active layer 132 may be made of an oxide semiconductor material. The second active layer 132 may be made of a material having a greater mobility than that of the first active layer 131.

The first active layer 131 may have a width greater than that of the second active layer 132. The second active layer 132 may be disposed only on a portion of the first active layer 131.

Referring to FIG. 13B, a gate insulating layer 140 may be formed on the active layer 130 and a gate material layer 150m may be formed on the gate insulating layer 140. The gate material layer 150m may be made of a material for forming the gate electrode 150. The gate material layer 150m may be made of, for example, metal.

In addition, referring to FIG. 13B, photoresist patterns 250 and 260 are formed on the gate material layer 150m. The reference numerals “250” and “260” of FIG. 13B indicate the same photoresist pattern, but are indicated by different codes because their cut cross-sections are different. The reference numeral “250” of FIG. 13B indicates the cross section of the photoresist pattern cut along I-I′ of FIG. 1, and the reference numeral “260” indicates the cross section of the photoresist pattern cut along II-II′ of FIG. 1.

Photoresist patterns 250, 260 can be formed by exposure using a half-tone mask, resulting in a height difference. Referring to FIG. 13B, an area overlapping the second channel part 130n2 of the photoresist pattern 260 has a relatively low height compared to other areas.

Referring to FIG. 13C, the gate electrode 150 is formed by etching the gate material layer 150m using the photoresist pattern 250, 260. A portion of the gate material layer 150m protected by the photoresist patterns 250 and 260 is not etched and becomes the gate electrode 150.

Subsequently, selective conductorization of the active layer 130 is performed. Selective conductorization of the active layer 130 may be performed by dopant doping or plasma treatment.

According to an embodiment of the present disclosure, as illustrated in FIG. 13C, dopant doping using the gate electrode 150 and the photoresist patterns 250 and 260 as a mask may be performed for selective conductorization. As the dopant, at least one of boron (B), phosphorus (P), fluorine (F), and hydrogen (H) may be used. A dopant may be selectively injected into the active layer 130 by dopant doping to selectively conduct the active layer 130. The dopant may be injected in an ionic state.

Although not shown, selective conductorization of the active layer 130 may be performed by plasma treatment. Specifically, in FIG. 13C, the gate insulating layer 140 may be patterned by selectively removing the gate insulating layer 140 by a dry etch using the gate electrode 150 and the photoresist patterns 250, 260 as a mask. As a result, a portion of the active layer 130 may be exposed from the gate insulating layer 140. The active layer 130 may be selectively conductorized by plasma treatment on the exposed active layer 130.

Referring to FIG. 13D, the active layer 130 is selectively conductorized by dopant doping, forming the first connection portion 130a or the second connection portion 130b. The first connection portion 130a or the second connection portion 130b corresponds to a selectively conductorized portion of the active layer 130.

Referring to FIG. 13E, ashing is performed on the photoresist patterns 250 and 260. As a result, a portion of the gate electrode 150 may be exposed from the photoresist patterns 250 and 260.

Referring to FIG. 13F, the portion of the gate electrode 150 exposed from the photoresist patterns 250 and 260 is removed. The portion of the gate electrode 150 may be removed by etching. Specifically, a portion of the gate electrode 150 overlapping the second channel part 130n2 is removed. In the step of removing the portion of the gate electrode 150, a portion of the gate electrode 150 overlapping the channel portion 130n is removed.

Next, referring to FIG. 13G, the photoresist patterns 250 and 260 are removed to complete the gate electrode 150.

Referring to FIG. 13H, an interlayer insulating layer 160 is formed on the gate electrode 150, and a source electrode 171 and a drain electrode 172 are formed on the interlayer insulating layer 160 to complete the thin film transistor 100.

Hereinafter, a display apparatus 800 according to another embodiment of the present disclosure will be described. The display apparatus 800 according to another embodiment of the present disclosure may include the thin film transistors 100, 200, 300, 400, 500, 600, and 700 described above.

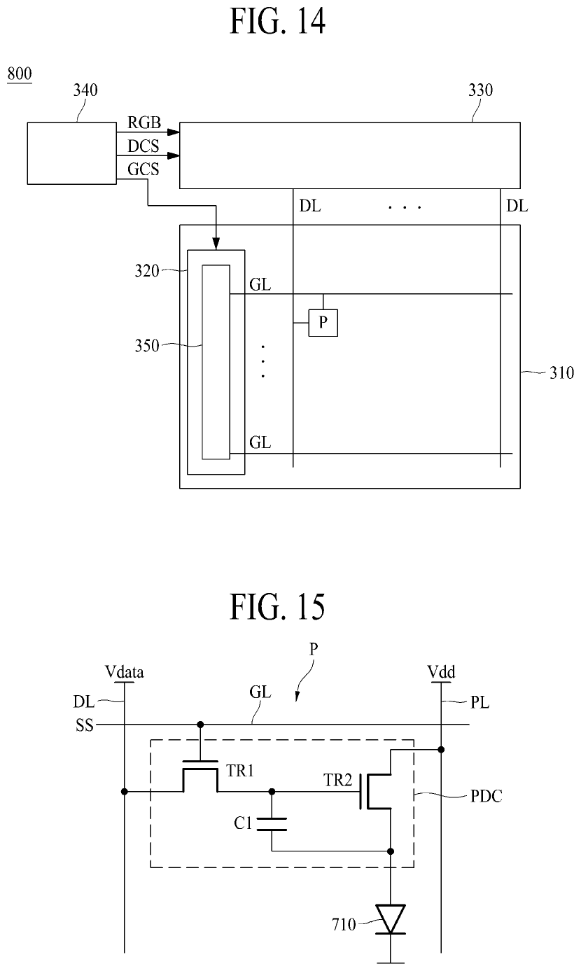

FIG. 14 is a schematic diagram of a display apparatus 800 according to another embodiment of the present disclosure.

A display apparatus 800 according to another embodiment of this disclosure may include a display panel 310, a gate driver 320, a data driver 330, and a control unit 340, as shown in FIG. 14.

Gate lines GL and data lines DL are disposed on the display panel 310, and pixels P are disposed at intersections of the gate lines GL and data lines DL. An image is displayed by driving the pixel P.

The controller 340 controls the gate driver 320 and the data driver 330.

The controller 340 outputs a gate control signal GCS for controlling the gate driver 320 and a data control signal DCS for controlling the data driver 330 by using a synchronization signal and a clock signal, which are supplied from an external system (not shown). Also, the controller 340 samples input image data input from the external system, realigns the sampled data and supplies the realigned digital image data RGB to the data driver 330.

The gate control signal GCS includes a gate start pulse GSP, a gate shift clock GSC, a gate output enable signal GOE, a start signal Vst, and a gate clock GCLK. Also, control signals for controlling a shift register may be included in the gate control signal GCS.

The data control signal DCS includes a source start pulse SSP, a source shift clock signal SSC, a source output enable signal SOE, and a polarity control signal POL.

The data driver 330 supplies a data voltage to the data lines DL of the display panel 310. In detail, the data driver 330 converts the image data RGB input from the controller 340 into an analog data voltage and supplies a data voltage of one horizontal line to the data lines DL.

The gate driver 320 may include a shift register 350.

The shift register 350 sequentially supplies gate pulses to the gate lines GL for one frame by using the start signal and the gate clock, which are transmitted from the controller 340. In this case, one frame means a time period when one image is output through the display panel 310. The gate pulse has a turn-on voltage that may turn on a switching element (thin film transistor) disposed in the pixel P.

Also, the shift register 350 supplies a gate-off signal capable of turning off a switching element, to the gate line GL for the other period of one frame, in which the gate pulse is not supplied. Hereinafter, the gate pulse and the gate-off signal will collectively be referred to as a scan signal SS or Scan.

According to one embodiment of the present disclosure, the gate driver 320 may be packaged on the substrate 310. In this way, a structure in which the gate driver 320 is directly packaged on the substrate 310 will be referred to as a Gate In Panel (GIP) structure.

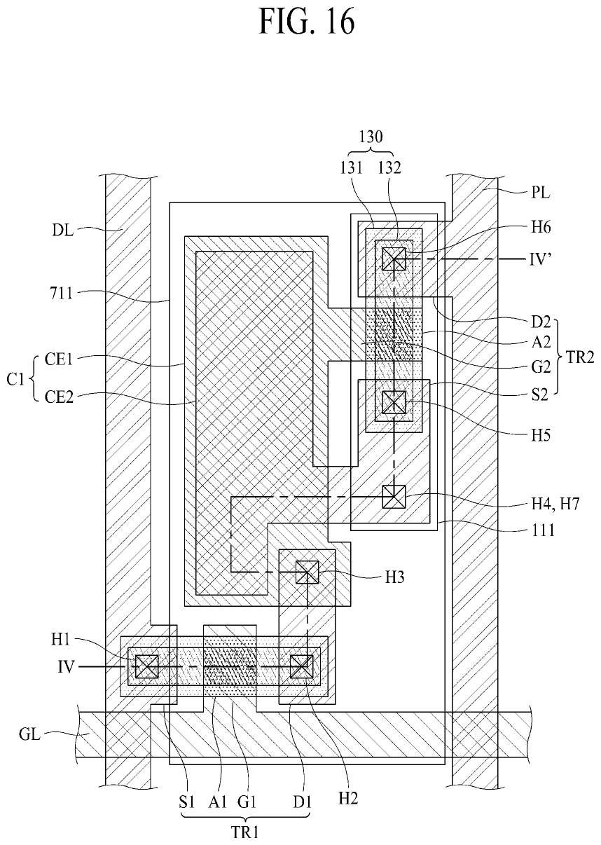

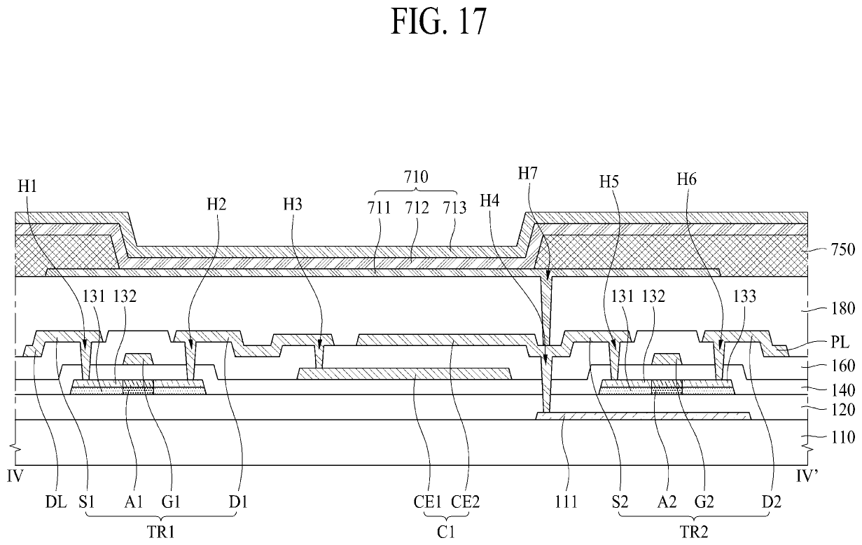

FIG. 15 is a circuit diagram of one pixel P of FIG. 14, FIG. 16 is a plan view of the pixel P of FIG. 15, and FIG. 17 is a cross-sectional view taken along IV-IV′ of FIG. 16.

The circuit view of FIG. 15 is an equivalent circuit view for a pixel P of a display device 800 that includes an organic light emitting diode (OLED) as a display element 710. The pixel P includes a display element 710, and a pixel driving circuit PDC for driving the display element 710.

According to another embodiment of the present disclosure, the display device 800 includes a pixel driving circuit PDC and a display element 710 connected to the pixel driving circuit PDC. The pixel driving circuit PDC may include any one of the thin film transistors 100, 200, 300, 400, 500, 600, and 700 described above. Specifically, the pixel driving circuit PDC includes a first thin film transistor TR1 and a second thin film transistor TR2, and any one of the above-described thin film transistors 100, 200, 300, 400, 600, and 700 may be used as one of the first thin film transistor TR1 and the second thin film transistor TR2. Any one of the above-described thin film transistors 100, 200, 300, 400, 500, 600, 700 may be used as a driving transistor of the pixel driving circuit PDC.

According to another embodiment of the present disclosure, the first thin film transistor TR1 of FIG. 15 is a switching transistor, and the second thin film transistor TR2 is a driving transistor.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls applying of the data voltage Vdata.

A driving power line PL provides a driving voltage Vdd to the display element 710, and the second thin film transistor TR2 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 320 through the gate line GL, the data voltage Vdata supplied through the data line DL is supplied to a gate electrode of the second thin film transistor TR2 connected with the display element 710. The data voltage Vdata is charged in a first capacitor C1 formed between the gate electrode and a source electrode of the second thin film transistor TR2. It is a storage capacitor formed between the gate electrode G2 and the source electrode S2 of the second thin film transistor TR2.

The amount of a current supplied to the organic light emitting diode (OLED), which is the display element 710, through the second thin film transistor TR2 is controlled in accordance with the data voltage Vdata, whereby gray scale of light emitted from the display element 710 may be controlled.

Referring to FIGS. 16 and 17, the first thin film transistor TR1 and the second thin film transistor TR2 are disposed on the substrate 110.

The substrate 110 may be made of glass or plastic. Plastic having flexibility properties, for example, polyimide (PI), may be used as the substrate 110.

The light blocking layer 111 is disposed on the substrate 110. The light blocking layer 111 may protect the active layer A2 by blocking light incident from the outside.

The buffer layer 120 is disposed on the light blocking layer 111. The buffer layer 120 is made of an insulating material and protects the active layers A1 and A2 from moisture or oxygen flowing from the outside.

The active layer A1 of the first thin film transistor TR1 and the active layer A2 of the second thin film transistor TR2 are disposed on the buffer layer 120. The active layers A1 and A2 may include, for example, an oxide semiconductor material. The active layers A1 and A2 may be formed of an oxide semiconductor layer made of an oxide semiconductor material.

The active layers A1 and A2 may include a first active layer 131 and a second active layer 132, respectively. Since the first active layer 131 and the second active layer 132 have already been described, detailed descriptions of the first active layer 131 and the second active layer 132 are omitted to avoid overlapping.

In addition, the active layers A1 and A2 may include a channel portion, a first connection portion in contact with one side, namely a first side, of the channel portion, and a second connection portion in contact with the other side, namely a second side, of the channel portion, separated from the first connection portion. Since the channel portion 130n, the first connection portion 130a, and the second connection portion 130b have already been described, detailed descriptions of the channel portion 130n, the first connection portion 130a, and the second connection portion 130b will be omitted to avoid overlapping.

A gate insulating layer 140 is disposed on the active layers A1 and A2.

A gate electrode G1 of the first thin film transistor TR1 and a gate electrode G2 of the second thin film transistor TR2 are disposed on the gate insulating layer 140.

In addition, a gate line GL may be disposed on the gate insulating layer 140. The gate electrode G1 of the first thin film transistor TR1 may extend from the gate line GL. However, one embodiment of this disclosure is not limited to this, and a part of the gate line GL may be the gate electrode G1 of the first thin film transistor TR1.

Referring to FIGS. 16 and 17, a first capacitor electrode CE1 for configuring a capacitor C1 is disposed on a gate insulating layer 140. The first capacitor electrode CE1 may be connected to the gate electrode G2 of the second thin film transistor TR2. The first capacitor electrode CE1 may be integrally formed with the gate electrode G2 of the second thin film transistor TR2.

An interlayer insulating layer 160 is placed on the gate electrode G1 of the first thin film transistor TR1, the gate electrode G2, the gate line GL, and the first capacitor electrode CE1. The interlayer insulating layer 160 may be made of an organic or inorganic insulating material.

The source electrode S1 and the drain electrode D1 of the first thin film transistor TR1 are disposed on the interlayer insulating layer 160. In addition, the source electrode S2 and the drain electrode D2 of the second thin film transistor TR2 are disposed on the interlayer insulating layer 160. A second capacitor electrode CE2 for configuring the data line DL, the driving power line PL, and the capacitor C1 may be disposed on the interlayer insulating layer 160.

A portion of the data line DL may extend to form the source electrode S1 of the first thin film transistor TR1. The source electrode S1 of the first thin film transistor TR1 may be connected to the active layer A1 through the contact hole H1.

The drain electrode D1 of the first thin film transistor TR1 is connected to the active layer A1 through the contact hole H2. In addition, the drain electrode D1 of the first thin film transistor TR1 may be connected to the first capacitor electrode CE1 through another contact hole H3.

A portion of the driving power line PL may extend to form the drain electrode D2 of the second thin film transistor TR2. The drain electrode D2 of the second thin film transistor TR2 is connected to the active layer A2 through the contact hole H6.

The source electrode S2 of the second thin film transistor TR2 may be connected to the active layer A2 through the contact hole H5, and may be connected to the light blocking layer 111 through another contact hole H4.

The source electrode S2 of the second thin film transistor TR2 and the second capacitor electrode CE2 may be connected to each other. The source electrode S2 of the second thin film transistor TR2 and the second capacitor electrode CE2 may be integrally formed.

The first capacitor electrode CE1 and the second capacitor electrode CE2 overlap each other to form the capacitor C1.

A planarization layer 180 is disposed on the source electrode S1 and the first drain electrode D1 of the first thin film transistor TR1, the source electrode S2, the second drain electrode D2, the data line DL, the driving power line PL, and the second capacitor electrode CE2 of the second thin film transistor TR2.

The planarization layer 180 consists of an insulation layer, flattening the upper parts of the first thin film transistor TR1 and the second thin film transistor TR2 and protecting the first thin film transistor TR1 and the second thin film transistor TR2.

The first pixel electrode 711 of the display element 710 is disposed on the planarization layer 180. The first pixel electrode 711 is in contact with the second capacitor electrode CE2 through a contact hole 7 formed in the planarization layer 180. As a result, the first pixel electrode 711 may be connected to the source electrode S2 of the second thin film transistor TR2.

A bank layer 750 is disposed at an edge of the first pixel electrode 711. The bank layer 750 defines a light emitting area of the display element 710.

An organic light emitting layer 712 is disposed on the first pixel electrode 711, and a second pixel electrode 713 is disposed on the organic light emitting layer 712. Accordingly, the display element 710 is completed. The display element 710 illustrated in FIGS. 16 and 17 is an organic light emitting diode OLED. Accordingly, the display device 800 according to another embodiment of the present disclosure is an organic light emitting display device.

In the above, the display device 800 has been described centering on a structure in which the pixel driving circuit PDC has two transistors and one capacitor. However, another embodiment of this disclosure is not limited to this, and the pixel driving circuit PDC may be formed in various structures other than those described above. The pixel driving circuiting circuit PDC may include, for example, three or more thin film transistors. In addition, the pixel driving circuit PDC may include, for example, two or more capacitors.

According to the present disclosure, the following advantageous effects may be obtained.

In the thin film transistor according to an embodiment of the present disclosure, a part of a channel portion does not overlap a gate electrode and is configured to be driven by a fringing electrical field generated in the gate electrode. As a result, the s-factor of the thin film transistor may be improved.

According to an embodiment of the present disclosure, since only a fringing electric field is applied to a part of the channel portion, a weak electric field is applied to a part of the channel portion. As a result, even if the gate voltage is applied, the rate of current increase in the channel portion decreases, and accordingly, the s-factor of the thin film transistor can be improved.

In addition, according to an embodiment of the present disclosure, the channel portion has at least one high mobility semiconductor layer, and all of the high mobility semiconductor layers are configured to overlap the gate electrode, so that the thin film transistor may have an improved on-current characteristics.

The display apparatus according to an embodiment of this disclosure uses a thin film transistor with a large s-factor and an improved on-current characteristics as a driving transistor, thereby having an improved gray scale expression ability and an improved current characteristics.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is intended to cover all variations or modifications derived from the meaning, scope and equivalent concept disclosed in the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin film transistor comprising:
an active layer; and
a gate electrode partially overlapping the active layer;
wherein the active layer includes:
a channel portion;
a first connection portion at a first side of the channel portion; and
a second connection portion at a second side of the channel portion, the second connection portion being spaced apart from the first connection portion;
wherein the channel portion includes:
a first channel part overlapping the gate electrode; and
a second channel part not overlapping the gate electrode;
wherein the active layer includes:
a first active layer; and
a second active layer on the first active layer;
wherein the second active layer includes a material having greater mobility than the first active layer,
wherein the first channel part includes the first active layer and the second active layer, and
wherein the second channel part includes the first active layer.

2. The thin film transistor of claim 1, wherein the second channel part is configured to be driven by a fringing electric field generated by the gate electrode.

3. The thin film transistor of claim 1, wherein the active layer is an oxide semiconductor layer including an oxide semiconductor material, and
wherein each of the first connection portion and the second connection portion is formed by selective conductorization of the oxide semiconductor layer.

4. The thin film transistor of claim 3, wherein the first channel part and the second channel part are non-conductorized parts of the active layer.

5. The thin film transistor of claim 1, wherein each of the first channel part and the second channel part extends from the first connection portion to the second connection portion.

6. The thin film transistor of claim 1, wherein the second channel part is parallel to a longitudinal direction of the channel portion, and
wherein the longitudinal direction of the channel portion is defined as a direction parallel to a direction connecting the first connection portion and the second connection portion.

7. The thin film transistor of claim 6, wherein a width of the second channel part is in a range of 10% to 50% with respect to a width of the channel portion, and
wherein the width of the second channel part is defined as a distance between both ends of the second channel part measured in a direction perpendicular to a length direction of the channel portion.

8. The thin film transistor of claim 1, wherein an area of the second active layer disposed in the second channel part is in a range of 50% or less with respect to a total area of the second channel part.

9. The thin film transistor of claim 1, wherein the second active layer is not disposed on the second channel part.

10. The thin film transistor of claim 1, wherein an area of the second active layer disposed in the first channel part is in a range of 90% or more with respect to a total area of the first channel part.

11. The thin film transistor of claim 1, wherein the second active layer is disposed in an entire region of the first channel part, in a plan view.

12. The thin film transistor of claim 1, wherein the active layer further includes a third active layer on the second active layer, and
wherein at least a part of the third active layer is disposed in the first channel part.

13. The thin film transistor of claim 12, wherein the third active layer is not disposed in the second channel part.

14. The thin film transistor of claim 12, wherein the third active layer is disposed in both the first channel part and the second channel part.

15. The thin film transistor of claim 1, wherein the gate electrode includes a plurality of protrusion parts spaced apart from each other in a plan view, and
wherein the second channel part is disposed between the protrusion parts adjacent to each other.

16. The thin film transistor of claim 15, wherein the plurality of protrusion parts protrudes in a width direction of the channel portion, and
wherein a width direction of the channel portion is defined in a direction perpendicular to a direction connecting the first connection portion and the second connection portion.

17. A manufacturing method of a thin film transistor, the manufacturing method comprising:
forming an active layer on a substrate;
forming a gate insulating layer on the active layer;
forming a gate material layer on the gate insulating layer;
forming a photoresist pattern on the gate material layer;
forming a gate electrode by etching the gate material layer using the photoresist pattern as a mask;
selectively conductorizing the active layer;
removing a part of the photoresist pattern so that a part of the gate insulating layer is exposed from the photoresist pattern; and
removing a part of the gate electrode exposed from the photoresist pattern.

18. The manufacturing method of the thin film transistor of claim 17, in selectively conductorizing the active layer, a part of the active layer is not conductorized and becomes a channel portion, and
in removing a part of the gate electrode, a part of the gate electrode overlapping the channel portion is removed.

19. A display apparatus comprising:
a pixel driving circuit; and
a display element electrically connected to the pixel driving circuit;
wherein the pixel driving circuit includes a thin film transistor including:
an active layer; and
a gate electrode partially overlapping the active layer;
wherein the active layer includes:
a channel portion;
a first connection portion at a first side of the channel portion; and
a second connection portion at a second side of the channel portion, the second connection portion spaced apart from the first connection portion;
wherein the channel portion includes:
a first channel part overlapping the gate electrode; and
a second channel part not overlapping the gate electrode;
wherein the active layer includes:
a first active layer; and
a second active layer on the first active layer;
wherein the second active layer includes a material having greater mobility than the first active layer,
wherein the first channel part includes the first active layer and the second active layer, and
wherein the second channel part includes the first active layer.

20. The display apparatus of claim 19, wherein the thin film transistor is a driving transistor electrically connected to the display element and is configured to drive the display element.
